(19) United States
(12) Patent Application Publication
(10) Pub. No.: US 2025/0374750 A1
(43) Pub. Date: Dec. 4, 2025

(54) COMPOSITE, FILM, AND PHOTOELECTRIC DEVICE

(71) Applicants: Guangdong Juhua Research Institute of Advanced Display, Guangzhou (CN); Shenzhen TCL High-Tech Development Co., Ltd., Shenzhen (CN)

(72) Inventor: Jianglei LUO, Guangzhou (CN)

(73) Assignees: Guangdong Juhua Research Institute of Advanced Display, Guangzhou (CN); Shenzhen TCL High-Tech Development Co., Ltd., Shenzhen (CN)

(21) Appl. No.: 19/224,639

(22) Filed: May 30, 2025

(30) Foreign Application Priority Data
May 31, 2024 (CN) 202410704582.5

(51) Int. Cl. H10K 50/15; H10K 50/115; H10K 50/17; H10K 85/10

(52) U.S. Cl. CPC H10K 50/15; H10K 50/115; H10K 50/171; H10K 85/111

(57) ABSTRACT

Disclosed are a composite, a film, and a photoelectric device. The composite material includes a first material and a second material. The first material is an organic P-type semiconductor material, and the second material is selected from one or more of phosphorene and a first metal element doped phosphorene. The composite has good conductivity and film-forming quality.

This application claims priority to Chinese Application No. 202410704582.5, entitled “COMPOSITE, FILM, AND PHOTOELECTRIC DEVICE”, filed on May 31, 2024. The entire disclosures of the above application are incorporated herein by reference.

### TECHNICAL FIELD

The present disclosure relates to a field of photoelectric materials, and in particular to a composite, a film, and a photoelectric device.

### BACKGROUND

A hole functional material refers to a material that easily loses electrons to form positively charged vacancies (holes), and controls migration of holes in an orderly direction to transport charges under an electric field, and/or a material that reduce hole injection barriers. The hole functional material includes a hole transport material and a hole injection material according to a function division.

The hole-functional material may be an organic hole-functional material or an inorganic hole-functional material. The organic hole-functional material has an advantage of high film-forming quality, but the organic hole-functional material has poor conductivity. The inorganic hole-functional material has good conductivity, but the inorganic hole-functional material has a problem of poor film-forming quality. Thus, a performance of a device including the hole functional material is not good.

### Technical Solution

In view of this, the present disclosure provides a composite, a film, and a photoelectric device.

According to a first aspect, the present disclosure provides a composite including a first material and a second material. The first material is an organic P-type semiconductor material, and the second material is selected from one or more of phosphorene and a first metal element doped phosphorene.

According to a second aspect, the present disclosure further provides a film including a composite. The composite includes a first material and a second material. The first material is an organic P-type semiconductor material, and the second material is selected from one or more of phosphorene and a first metal element doped phosphorene.

According to a third aspect, the present disclosure further provides a photoelectric device including an anode, a cathode, and a functional layer disposed between the anode and the cathode. The functional layer includes multiple functional sublayers disposed in stack, and a material of at least one of the multiple functional sublayers includes a second material selected from one or more of phosphorene and a first metal element doped phosphorene.

According to the composite provided by the present disclosure, the presence of the first material is beneficial to improving film-forming quality of the composite, and the presence of the second material is beneficial to improving a conductivity of the composite and reducing a band gap of the composite, thus the composite has good conductivity and film-forming quality.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings might be obtained based on these drawings.

FIG. 1 is a schematic diagram of a photoelectric device provided by an embodiment of the present disclosure.

### DETAILED DESCRIPTION

Technical solutions in embodiments of the present disclosure will be clearly and completely described below in conjunction with drawings in the embodiments of the present disclosure. Obviously, the embodiments are only a part of embodiments of the present disclosure, rather than all the embodiments. Based on the embodiments in the present disclosure, all other embodiments obtained by those skilled in the art without creative work fall within the protection scope of the present disclosure.

Unless otherwise defined, all professional and scientific terms used herein have same meanings as those familiar to those skilled in the art. Furthermore, any method or any material similar or equivalent to that described might be used in the present disclosure. A preferred embodiment and a preferred material described herein are for illustrative purposes only, but are not intended to limit contents of the present disclosure.

An order of description of the following embodiments is not intended to limit a preferred order of the embodiments.

Each embodiment of the present disclosure may be presented in a form of range. It should be understood that a description in the form of range is merely for convenience and brevity, and should not be construed as a limitation on the scope of the disclosure. Accordingly, it should be considered that a recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, 6, and the like, which is applicable for any range. Additionally, whenever a range of values is indicated herein, it is meant to include any recited number (fractional or integer) within the indicated range.

In the present disclosure, “including” means “including but not limited to”.

In the present disclosure, “at least one” refers to one or more, and “more” in the “one or more” refers to two or more. “one or more”, “at least one of the followings”, or similar expressions thereof refer to any combination of items listed, including any combination of a singular item or multiple items. For example, “at least one of a, b, or c”, or “at least one of a, b, and c”, may each represent: a, b, c, a-b (i.e., a and b), a-c, b-c, or a-b-c. Each of a, b, and c may be single or plural.

In the present disclosure, “and/or” is used to describe an association of associated objects. For example, “A and/or B” may refer to three cases: a first case refers to the presence of A alone, a second case refers to the presence of both A and B, and a third case refers to the presence of B alone, where A and B each may be singular or plural.

In the present disclosure, a description of “the A layer is formed on a side of the B layer” or “the A layer is formed on a side of the B layer away from the C layer” may mean that the A layer is directly formed on the side of the B layer or the side of the B layer away from the C layer, that is, the A layer is in contact with the B layer. It may also mean that the A layer is indirectly formed on the side of the B layer or the side of the B layer away from the C layer, that is, another film layer may be formed between the A layer and the B layer.

In the present disclosure, “particle size” refers to a diameter of a nanoparticle.

In the present disclosure, “an organic hole transport material” refers to an organic compound that easily loses electrons to form positively charged vacancies (holes), and controls migration of holes in an ordered direction to transport charges under an electric field.

In the present disclosure, “an organic hole injection material” refers to an organic compound that easily loses electrons to form positively charged vacancies (holes), and controls injection of holes in an ordered direction to transport charges under an electric field.

In the present disclosure, “phosphorene” refers to black phosphorene or a two-dimensional black phosphorus material. The phosphorene is a two-dimensional semiconductor material with a single atomic layer and a direct band gap composed of ordered phosphorus atoms peeled from black phosphorus. In some embodiments of the present disclosure, the phosphorene is purchased from Aladdin with article number B196539.

In a first aspect, an embodiment of the present disclosure provides a composite including a first material and a second material. The first material is an organic P-type semiconductor material, and the second material is selected from one or more of phosphorene and a first metal element doped phosphorene. The presence of the first material is beneficial to improving film-forming quality of the composite, and the presence of the second material is beneficial to improving a conductivity of the composite and reducing a band gap of the composite, thus the composite has good conductivity and film-forming quality.

In order to further improve the film-forming quality of the composite and ensure that the composite has a good hole transport property, in some embodiments, a mass ratio of the second material to the first material is 1: (30˜70), such as 1:30, 1:40, 1:50, 1:60, 1:70, or a value between any two thereof.

The first metal element is selected from one or more of Group IA metal elements, Group IIA metal elements, Group IIIA metal elements, Group IVA metal elements, Group VA metal elements, and transition metal elements. In some embodiments, the first metal element is selected from one or more of Cr, Mg, Fe, Co, and Ni. Furthermore, a band gap of the first metal element doped phosphorene ranges from 0.2 eV to 0.4 eV, such as 0.4 eV, 0.5 eV, 0.8 eV, 1.0 eV, 1.5 eV, 2.0 eV, or a value between any two thereof.

The band gap of the first metal element doped phosphorene is calculated by the first principle thinking, and a sub-exchange correlation energy is obtained by the generalized gradient approximation of Perdew-Burke-Ernzerh (GGA-PBE). A thickness of a vacuum region is greater than 20 A to avoid interlayer interaction, a network of 5×7×1 Monkhorst-packk-point is used for structural relaxation, a denser grid 7×10×1 is used to calculate a band structure, and all doped systems are optimized. Among them, a plane wave cut-off energy is 500 eV, a convergence energy is less than 5×10⁻⁶ eV/atom, and a lattice constant of black phosphorene is calculated as 3.29×4.62 Å.

In order to further improve the structural stability and electrical conductivity of the first metal element doped phosphorene, in some embodiments, in the first metal element doped phosphorene, an atomic percentage of the first metal element ranges from 1% to 5%, such as 1%, 2%, 3%, 4%, 5%, or a value between any two thereof.

In order to further improve the structural stability and electrical conductivity of the first metal element doped phosphorene, in some embodiments, the first metal element doped phosphorene has a layered structure, and a number of layers of the layered structure ranges from one layer to ten layers, such as one layer, three layers, five layers, seven layers, or ten layers. An average sheet diameter of the first metal element doped phosphorene ranges from 100 nm to 200 nm, and the average sheet diameter is measured by a transmission electron microscope.

In some embodiments, the organic P-type semiconductor material is selected from one or more of an organic hole transport material and an organic hole injection material.

In some embodiments, the organic hole injection material is selected from one or more of poly(3,4-ethylenedioxythiophene)-poly(styrenesulfonate) (PEDOT:PSS, CAS: 155090-83-8), copper(II) phthalocyanine (CAS: 147-14-8), titanyl phthalocyanine (CAS: 26201-32-1), 2,3,5,6-tetrafluoro-7,7,8,8-tetracyanoquinodimethane (CAS: 29261-33-4), and hexaazatriphenylenehexacabonitrile (CAS: 105598-27-4).

In some embodiments, the organic hole transport material is selected from one or more of polyaniline (CAS: 25233-30-1), polypyrrole (CAS: 30604-81-0), poly(3-hexylthiophene-2,5-diyl)(CAS: 104934-50-1), poly(n-vinylcarbazole)(PVK, CAS: 25067-59-8), 4,4′-Bis(N-carbazolyl)-1,1′-biphenyl (CBP, CAS: 58328-31-7), poly[N,N′-bis(4-butylphenyl)-N,N′-bis(phenyl)-benzi (CAS: 472960-35-3), 4,4′-cyclohexylidenebis[N,N-bis(4-methylphenyl)aniline](TAPC, CAS: 58473-78-2), poly(9,9-dioctylfluorene-co-N-(4-butylphenyl)diphenylamine) (TFB, CAS: 220797-16-0), poly[(9,9-dioctylfluorenyl-2,7-diyl)-alt-(4,4′-(N-(4-butylphenyl) (CAS: 223569-31-1), 4,4′,4″-tris(N-3-methylphenyl-N-phenylamino)triphenylamine (CAS: 124729-98-2), 4,4′,4″-tris(carbazol-9-yl)-triphenylamine(TCTA, CAS: 139092-78-7), 4,4′,4″-tris[2-naphthyl(phenyl)amino]triphenylamine (CAS: 185690-41-9), N,N′-bis-(1-naphthalenyl)-N,N′-bis-phenyl-(1,1′-biphenyl)-4,4′-diamine (NPB, CAS: 123847-85-8), N,N′-bis(3-methylphenyl)-N,N′-diphenyl-benzidine (TPD, CAS: 65181-78-4), N,N′-bis[4-(diphenylamino)phenyl]-N,N′-diphenylbenzidine (CAS: 209980-53-0), N2,N7-diphenyl-N2,N7-di-m-tolyl-9,9′-spirobi[fluorene]-2,7-diamine (Spiro-TPD, CAS: 1033035-83-4), N2,N7-di-1-naphthalenyl-N2,N7-diphenyl-9,9′-spirobi[9h-fluorene]-2,7-diamine (CAS: 932739-76-9), poly[bis(4-phenyl)(2,4,6-trimethylphenyl)amine](PTTA, CAS: 1333317-99-9), and 2,2′,7,7′-Tetrakis[N,N-di(4-methoxyphenyl)amino]-9,9′-spirobifluorene (Spiro-omeTAD, CAS: 207739-72-8).

In order to further improve the film-forming quality and conductivity of the composite, in some embodiments, the first material is selected from one or more of poly(9,9-dioctylfluorene-co-N-(4-butylphenyl) diphenylamine), polyaniline, and polypyrrole, and the second material is iron-doped phosphorene.

In some embodiments, a method for preparing the first metal element doped phosphorene includes steps that a solid phosphorene and a powdery metal are mixed according to a doping atomic percentage of the first metal element to obtain a mixture, and the mixture is placed in a ball mill for ball milling to obtain the first metal element doped phosphorene.

In a second aspect, an embodiment of the present disclosure provides a film including the composite described above. The film has good surface flatness as well as hole mobility.

In a third aspect, an embodiment of the present disclosure provides a method for preparing the film including steps that a dispersion liquid including the composite is deposited, and then the dispersion liquid deposited is subjected to a drying treatment to obtain the film.

A dispersion medium of the dispersion liquid may include but not limited to one or more of an alkane, an aromatic hydrocarbon, a halogenated alkane, an alcohol compound, an ether compound, a ketone compound, an ester compound, a furan compound, a pyridine compound, an amide compound, and a sulfone compound.

The alkane may include but not limited to one or more of nonane, decane, dodecane, terpene, butylcyclohexane, N-octane, N-hexane, N-heptane, N-nonane, N-decane, cyclohexane, and cyclopentane. The aromatic hydrocarbons may include but not limited to one or more of diethylbenzene, trimethylbenzene, n-propylbenzene, cumene, p-cymene, butylbenzene, 1-methylnaphthalene and indene. The halogenated alkane may include but not limited to one or more of dichloromethane, trichloromethane, and carbon tetrachloride. The alcohol compound may include but not limited to one or more of methanol, ethanol, 1-propanol, 1-butanol, ethylene glycol, and glycerin. The ether compound may include but not limited to one or more of 2-methoxyethanol, ethyl ether, and propylene oxide. The ketone compound may include but not limited to one or more of propanone, 2-butanone, and N-methylpyrrolidone. The ester compound may include but not limited to one or more of ethyl formate, ethyl acetate and n-Propyl acetate. The furan compound may include but not limited to one or more of tetrahydrofuran and 2-methylfuran. The pyridine compound may include but not limited to pyridine. The amide compound may include but not limited to N, N-dimethylformamide. The sulfone compound may include but not limited to dimethyl sulfoxide.

In some embodiments, in the dispersion liquid including the composite, a total concentration of the first material and the second material ranges from 5 mg/mL to 30 mg/mL.

In some embodiments, a method for preparing the dispersion liquid includes a step that the first material and the second material are mixed and dispersed in the dispersion medium.

In other embodiments, a method for preparing the dispersion liquid includes a step that the second material is dispersed in a dispersion liquid including the first material.

In other embodiments, a method for preparing the dispersion liquid includes a step that the first material is dispersed in a dispersion liquid including the second material.

A method for dispersion includes but not limited to one or more of a heating dispersion, an ultrasonic dispersion, and a stirring dispersion, and the dispersion liquid including the second material is commercially available. A temperature of the heating dispersion ranges from 50° C. to 80° C.

A deposition method of the dispersion liquid including the composite includes but not limited to one or more of a spin coating method, a printing method, an ink jet printing method, a blade coating method, a dipping and pulling method, a soaking method, a spray coating method, a roll coating method, a casting method, a slit coating method, and a strip coating method.

The drying treatment includes but not limited to one or more of heating and vacuum drying.

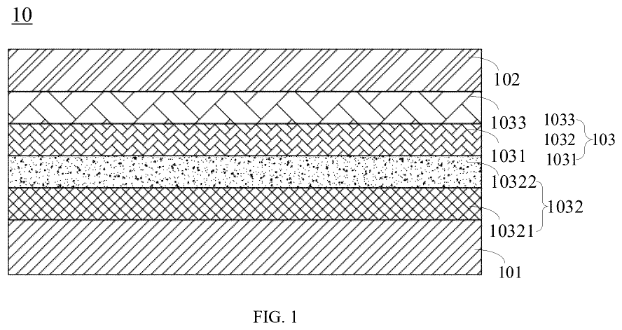

In a fourth aspect, an embodiment of the present disclosure provides a photoelectric device. The photoelectric device includes but not limited to a light-emitting device, a solar cell or a photodetector. Referring to FIG. 1, the photoelectric device includes 10 an anode 101 and a cathode 102 disposed oppositely, and a functional layer 103 disposed between the anode 101 and the cathode 102. The functional layer 103 includes multiple functional sublayers disposed in stack, and a material of at least one of the multiple functional sublayers includes the second material as described above.

In some embodiments, a material of the anode 101 and a material of the cathode 102 are each independently selected from one or more of a metal, a carbon material, and a first metal oxide material. The metal includes but not limited to one or more of Al, Ag, Cu, Mo, Au, Ba, Pt, Ca, Ir, Ni, and Mg. The carbon material includes but not limited to one or more of graphite, carbon nanotube, graphene, and carbon fiber. The first metal oxide includes but not limited to one or more of indium tin oxide (ITO), fluorine-doped tin oxide (FTO), antimony tin oxide (ATO), aluminium-doped zinc oxide (AZO), gallium-doped zinc oxide (GZO), indium-doped zinc oxide (IZO), magnesium-doped zinc oxide (IZO), TiO₂, SnO₂, ZnO, and In₂O₃.

The anode 101 or the cathode 102 may be a composite electrode which has a sandwich-like structure. A material of an upper layer and a material of a bottom layer are each independently selected from the first metal oxide material or a metal sulfide, and a material of an intermediate layer is the metal. For example, the composite electrode is selected from one or more of AZO/Ag/AZO, AZO/Al/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂, and TiO₂/Al/TiO₂. An average thickness of the intermediate layer does not exceed 35 nm. An average thickness of the anode 101 may range from 20 nm to 300 nm, and an average thickness of the cathode 102 may range from 20 nm to 300 nm.

In order to further improve an overall performance of the photoelectric device 10, in some embodiments, the material of at least one of the multiple functional sublayers further includes the first material as described above.

In order to improve a hole transport efficiency of the photoelectric device 10, in some embodiments, referring to FIG. 1, the multiple functional sublayers include a hole functional layer 1032 including one or more of a hole injection layer 10321 and a hole transport layer 10322, and when the hole functional layer 1032 includes the hole injection layer 10321 and the hole transport layer 10322, the hole injection layer 10321 is closer to the anode 101 than the hole transport layer 10322. A material of the hole injection layer 10321 includes the second material, or the material of the hole injection layer 10321 is formed of the first material and the second material, and the first material is the organic hole injection material. A material of the hole transport layer 10322 includes the second material, or the material of the hole transport layer 10322 is formed of the first material and the second material, and the first material is the organic hole transport material.

The hole functional layer 1032 may have a single-layer structure or a multi-layers structure, and a thickness of the hole functional layer 1032 may range from 10 nm to 100 nm. In addition to the organic hole transport material and the organic hole injection material, a hole functional material commonly used includes a first inorganic compound and/or a doped-type second inorganic compound. The first inorganic compound includes but not limited to one or more of graphene, fullerene C60, nickel oxide, molybdenum oxide, tungsten oxide, vanadium oxide, p-type gallium nitride, chromium oxide, copper oxide, copper sulfide, molybdenum sulfide, and tungsten sulphide. A doping element of the doped-type second inorganic compound is selected from one or more of nickel, molybdenum, tungsten, vanadium, chromium, copper and platinum group metal elements, a percentage of a molar amount of the doping element to a total molar amount of the doped-type second inorganic compound is not more than 50%, and a host compound of the doped-type second inorganic compound includes but not limited to one or more of graphene, fullerene C60, nickel oxide, molybdenum oxide, tungsten oxide, vanadium oxide, p-type gallium nitride, chromium oxide, copper oxide, copper sulfide, molybdenum sulfide, or tungsten sulphide.

In some embodiments, referring to FIG. 1, the multiple functional sublayers further include a light-emitting layer 1031 disposed between the hole functional layer 1032 and the cathode 102. A material of the light-emitting layer 1031 includes an organic light-emitting material and a quantum dot.

The organic light-emitting material may include but not limited to one or more of 4,4′-bis(N-carbazole)-1,1′-biphenyl: tris[2-(p-tolyl) pyridinyl iridium (III)](CBP:Ir(mppy)₃), 4,4,4″-tris(carbazol-9-yl)triphenylamine: tris[2-(p-tolyl)pyridinyl iridium](TCTX:Ir(mmpy)), diarylanthracene derivatives, stilbene aromatic derivatives, pyrene derivatives, fluorene derivatives, a TBPe fluorescent material, a TTPX fluorescent material, a TBRb fluorescent material, a DBP fluorescent material, a DBP fluorescent material, a DBP fluorescent material, a delayed fluorescence material, a TTA material, a thermally activated delayed fluorescence material, a polymer including a B—N covalent, a hybrid local charge transfer excited state material, an exciplex luminescent material, polyacetylene and derivatives thereof, polythiophene and derivatives thereof, and polyfluorene and derivatives thereof.

The quantum dot may include but not limited to one or more of a red quantum dot, a green quantum dot, and a blue quantum dot. The quantum dot light-emitting material may include but not limited to one or more of a quantum dot with a single component, a quantum dot with a core-shell structure, an inorganic perovskite quantum dot, an organic perovskite quantum dot, and an organic-inorganic hybrid perovskite quantum dot. The quantum dot with a core-shell structure includes one or more shell layers. An average particle size of the quantum dot light-emitting material may range from 2 nm to 20 nm, such as 2 nm, 5 nm, 8 nm, 10 nm, 13 nm, 15 nm, 20 nm, or a value between any two thereof.

For the quantum dot with a single component and the quantum dot with a core-shell structure, a material of the quantum dot with a single component, a material of the core of the quantum dot with a core-shell structure, and a material of a shell layer of the quantum dot with a core-shell structure each include one or more of a group II-VI compound, a group IV-VI compound, a group III-V compound, a group III-VI compound, and a group I-III-VI compound.

The group II-VI compound may include but not limited to one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The group IV-VI compound may include but not limited to one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. The group III-VI compound may include but not limited to one or more of In₂S₃, In₂Se₃, InGaS₃, and InGaSe₃. The group III-V compound may include but not limited to one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAPSb, GaInNP, GaInNAs, GaInNSb, GaInPAs, GaInPSb, InAlNP, InAlNAs, InAlNSb, InAlPAs, and InAlPSb. The group I-III-VI compound may include but not limited to one or more of AgInS, AgInS₂, CuInS, CuInS₂, AgGaS₂, CuGaS₂, CuGaO₂, AgGaO₂, AgAlO₂, AgInGaS₂, and CuInGaS₂.

The inorganic perovskite quantum dot has a general structural formula of AMX₃. A is Cs⁺, M is a divalent metal cation including but not limited to Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion including but not limited to Cl⁻, Br⁻, or I⁻.

The organic perovskite quantum dot has a general structural formula of CMX₃. C is a formamidyl, M is a divalent metal cation including but not limited to Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion including but not limited to Cl⁻, Br⁻, or I⁻.

The organic-inorganic hybrid perovskite quantum dot has a general structural formula of BMX₃. B is an organic amine cation including but not limited to CH₃(CH₂)ₙ₋₂NH³⁺ or NH₃(CH₂)ₙNH₃²⁺, n is not less than 2, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion selected from one or more of Cl⁻, Br⁻, or I⁻.

In some embodiments, when the material of the light-emitting layer 1031 includes the quantum dot, the quantum dot is attached with a ligand, thereby improving a solution processing performance of the quantum dot, and further improving a device efficiency of the photoelectric device 10. The ligand may be a ligand known in the art, including but not limited to one or more of a C1˜C30 aliphatic carboxylic acid ligand, a C6˜C30 aromatic carboxylic acid ligand, a C1˜C30 aliphatic thiol ligand, a C6˜C30 aromatic thiol ligand, a C1˜C30 aliphatic amine ligand, a C6˜C30 aromatic amine ligand, a C1˜C30 aliphatic phosphine ligand, a C6˜C30 aromatic phosphine ligand, a C6˜C30 aromatic phosphate ester ligand, and a halogen ligand.

The C1˜C30 aliphatic carboxylic acid ligand includes but not limited to one or more of octanoic acid, nonanoic acid, decanoic acid, undecanoic acid, dodecanoic acid, tetradecanoic acid, hexadecanoic acid, octadecanoic acid, eicosanoic acid, tetracosanoic acid, hexacosanoic acid, oleic acid, linoleic acid, arachidic acid, arachidonic acid, erucic acid and docosahexaenoic acid. The C6˜C30 aromatic carboxylic acid ligand includes but not limited to one or more of benzoic acid, bibenzoic acid, and 1-naphthoic acid. The C1˜C30 aliphatic thiol ligand includes but not limited to one or more of hexanethiol, octanethiol, nonanethiol, decanethiol, undecanethiol, dodecanethiol, hexadecanethiol, and octadecanethiol. The C6˜C30 aromatic thiol ligand includes but not limited to one or more of thiophenol, triphenylmethyl mercaptan, and p-terphenyl-4,4″-dithiol. The C1˜C30 aliphatic amine ligand includes but not limited to one or more of hexylamine, octylamine, dioctylamine, trioctylamine, nonylamine, decylamine, dodecylamine, tridecylamine, tetradecylamine, pentadecylamine, hexadecylamine, heptadecylamine, octadecylamine, and oleylamine. The C6˜C30 aromatic amine ligand includes but not limited to one or more of aniline, aprindine, 4-octylaniline, and benzidine. The aliphatic phosphine ligand includes but not limited to one or more of trimethylphosphine, triethylphosphine, tripropylphosphine, tributylphosphine, trihexylphosphine, trioctylphosphine, tridecylphosphine, tributylphosphine oxide, trihexylphosphine oxide, trioctylphosphine oxide, and tridecylphosphine oxide. The C6˜C30 aromatic phosphine ligand includes but not limited to one or more of bis[2-(diphenylphosphino)ethyl]phenylphosphine and triphenylphosphine oxide. The C6˜C30 aromatic phosphate ester ligand includes but not limited to one or more of p-xylylenediphosphonic acid tetraethyl ester and diphenylphosphinic acid ethyl ester. The halogen ligand includes but not limited to one or more of —Cl, —F, —I, and —Br.

In some embodiments, referring to FIG. 1, the multiple functional sublayers further include an electron functional layer 1033 disposed between the hole functional layer 1032 and the cathode 102. When the photoelectric device 10 includes the light-emitting layer 1031, the electron functional layer 1033 disposed between the light-emitting layer 1031 and the cathode 102.

A thickness of the electron functional layer 1033 may range from 10 nm to 100 nm. The electron functional layer 1033 may have a single-layer structure or a multi-layers structure. When the electron functional layer 1033 has a multi-layers structure, the electron functional layer 1033 may include one or more of an electron injection layer, an electron transport layer, and a hole blocking layer.

In one embodiment, the electron functional layer 1033 includes the electron injection layer, the electron transport layer, and the hole blocking layer, the electron transport layer is disposed between the electron injection layer and the hole blocking layer, and the electron injection layer is closer to the cathode 102 than the hole blocking layer.

In another embodiment, the electron functional layer 1033 includes the electron transport layer and the hole blocking layer disposed in stack. The electron transport layer is closer to the cathode 102 than the hole blocking layer.

In another embodiment, the electron functional layer 1033 includes the electron injection layer and the electron transport layer disposed in stack. The electron injection layer is closer to the cathode 102 than the electron transport layer.

In some embodiments, a material of the electronic functional layer 1033 includes one or more of a second metal oxide material, a third metal oxide material, and a group IIB-VIA semiconductor material. The second metal oxide material includes but not limited to one or more of ZnO, TiO₂, and SnO₂. The group IIB-VIA semiconductor material includes one or more of ZnS, ZnSe, and CdS. The third metal oxide material includes a doped-type metal oxide, a doping element of the doped-type metal oxide is selected from one or more of Mg, Ca, Zr, W, Ga, Li, Al, Ti, Y, In, and Sn, and a host compound of the doped-type metal oxide is selected from ZnO, TiO₂, or SnO₂.

In some embodiments, the doped-type metal oxide is selected from one or more of magnesium zinc oxide, calcium zinc oxide, zirconium zinc oxide, gallium zinc oxide, aluminum zinc oxide, lithium zinc oxide, titanium zinc oxide, yttrium zinc oxide, indium tin oxide, and lithium titanium oxide. For example, the doped-type metal oxide is selected from one or more of Zn₍₁₋ₓ₎MgₓO, Zn₍₁₋ₓ₎CaₓO, Zn₍₁₋ₓ₎ZrₓO, Zn₍₁₋ₓ₎GaₓO, Zn₍₁₋ₓ₎AlₓO, Zn_{(1-X)}LiₓO, Zn₍₁₋ₓ₎TiₓO, Zn₍₁₋ₓ₎YₓO, In₍₁₋ₓ₎SnₓO, and Ti₍₁₋ₓ₁₎Liₓ₁O, where x is greater than 0 and not more than 0.5.

Under a condition that the electronic functional layer 1033 includes mutiple materials and the electronic functional layer 1033 has the multi-layers structure, the mutiple materials may all be in the same layer, or may be in different layers, or may be partially in the same layer. Each of the second metal oxide material and the doped-type metal oxide may be nanoparticles, nanosheets, nanoneedles or nanorods, for example, each of the second metal oxide material and the doped-type metal oxide may be nanoparticles, and an average particle size of the nanoparticles ranges from 2 nm to 50 nm.

In order to further improve performances of the photoelectric device 10, in some embodiments, referring to FIG. 1, the multiple functional sublayers are formed of the hole injection layer 10321, the hole transport layer 10322, the light-emitting layer 1031, and the electron functional layer 1033. The electron functional layer 1033 is, for example, an electron transport layer with a single-layer structure. The material of the hole injection layer 10321 is the organic hole injection material as described above, and the material of the hole transport layer 10322 is selected from one or more of the composite as described above or the first metal element doped phosphorene. An average thickness of the hole transport layer 10322 ranges from 10 nm to 40 nm, and an average thickness of the light-emitting layer 1031 ranges from 30 nm to 60 nm.

A method for preparing each layer in the photoelectric device 10 includes but not limited to a chemical method and/or a physical method. The chemical method includes but not limited to one or more of a chemical vapor deposition method, a continuous ion layer adsorption and reaction method, an anodic oxidation method, an electrolytic deposition method, and a co-precipitation method. The physical method includes but not limited to a physical coating method and a solution method. The physical coating method includes but not limited to one or more of a thermal evaporation coating method, an electron beam evaporation coating method, a magnetron sputtering method, a multi-arc ion coating method, a physical vapor deposition method, an atomic layer deposition method, and a pulsed laser deposition method. The solution method includes but not limited to one or more of a spin coating method, a printing method, an ink jet printing method, a blade coating method, a dipping and pulling method, a soaking method, a spray coating method, a roll coating method, a casting method, a slit coating method, and a strip coating method. After all layers of the photoelectric device 10 having been prepared, an encapsulating step is performed. The encapsulating step may be a commonly used machine encapsulating or a manually encapsulating. In the encapsulating environment, a content of oxygen and a content of water are both lower than 0.1 ppm to ensure a stability of the photoelectric device.

An embodiment of the present disclosure provides an electronic apparatus including the photoelectric device according to any one of the embodiments of the present disclosure. The electronic device may be any electronic product with a display function, including but not limited to a smartphone, a tablet personal computer, a notebook computer, a video telephone, an electronic book reader, a laptop personal computer, a netbook computer, a workstation, a server, a personal digital assistant, a portable multimedia player, a mobile medical machine, a camera, a game console, a car navigation, an electronic billboard, a smart wearable device, or a virtual reality device. The smart wearable device may be, for example, a smart bracelet, a smart watch, or the like.

In the following, the present disclosure is specifically described by specific embodiments, and the following examples are only partial examples of the present disclosure and are not limited to the present disclosure.

### Material Example 1

The present embodiment provides a composite and a film. The composite is formed of TFB and iron-doped phosphorene. In the composite, a mass ratio of TFB to iron-doped phosphorene is 50:1, and an atomic percentage of iron in the iron-doped phosphorene is 2.78%.

A material of the film includes the composite, and the film is made from the composite by a solution method. The solution method for preparing the film includes steps that a material dispersion with a concentration of 10 mg/mL is spin-coated on a substrate under a nitrogen atmosphere at a normal temperature and a normal pressure, and then the film with an average thickness of 30 nm is obtained by heating at 170° C. under a nitrogen atmosphere for 15 minutes. The material dispersion is prepared by steps that TFB, iron-doped phosphorene, and chlorobenzene are mixed and ultrasonically dispersed at 60° C. for 3 hours.

A method for preparing iron-doped phosphorene includes step S1.1 and step S1.2. In the step S1.1, solid phosphorene purchased from Aladdin with article number B196539 and iron powder are mixed according to a mass ratio of phosphorene to iron powder is 1:0.57 to obtain a mixture. In the step S1.2, the mixture is placed in a ball mill, a weight of ball milling media (agate balls) in the ball mill is 50 times of a weight of the mixture, and iron-doped phosphorene is obtained after ball milling with a rotating speed of 400 r/min for 70 minutes. A band gap of iron-doped phosphorene is 0.48 eV as calculated by the first principle thinking.

### Material Example 2

The present embodiment provides a composite and a film. Compared with the composite in Material Example 1, the composite in the present embodiment has a difference that the mass ratio of TFB to iron-doped phosphorene is 70:1.

Compared with the film in Material Example 1, the film in the present embodiment has a difference that a material of the film includes the composite in the present embodiment. A method for preparing the film in the present embodiment is carried out with reference to Material Example 1.

### Material Example 3

The present embodiment provides a composite and a film. Compared with the composite in Material Example 1, the composite in the present embodiment has a difference that the mass ratio of TFB to iron-doped phosphorene is 30:1.

Compared with the film in Material Example 1, the film in the present embodiment has a difference that a material of the film includes the composite in the present embodiment.

A method for preparing the film in the present embodiment is carried out with reference to Material Example 1.

### Material Example 4

The present embodiment provides a composite and a film. Compared with the composite in Material Example 1, the composite in the present embodiment has a difference that the atomic percentage of iron in the iron-doped phosphorene is 1%.

Compared with the film in Material Example 1, the film in the present embodiment has a difference that a material of the film includes the composite in the present embodiment. A method for preparing the film in the present embodiment is carried out with reference to Material Example 1.

Compared with the method for preparing iron-doped phosphorene in Material Example 1, a method for preparing iron-doped phosphorene in the present embodiment is different in that “solid phosphorene purchased from Aladdin with article number B196539 and iron powder are mixed according to a mass ratio of phosphorene to iron powder is 1:0.57 to obtain a mixture” is replaced with “solid phosphorene purchased from Aladdin with article number B196539 and iron powder are mixed according to a mass ratio of phosphorene to iron powder is 1:0.204 to obtain a mixture”.

### Material Example 5

The present embodiment provides a composite and a film. Compared with the composite in Material Example 1, the composite in the present embodiment has a difference that the atomic percentage of iron in the iron-doped phosphorene is 5%.

Compared with the film in Material Example 1, the film in the present embodiment has a difference that a material of the film includes the composite in the present embodiment. A method for preparing the film in the present embodiment is carried out with reference to Material Example 1.

Compared with the method for preparing iron-doped phosphorene in Material Example 1, a method for preparing iron-doped phosphorene in the present embodiment is different in that “solid phosphorene purchased from Aladdin with article number B196539 and iron powder are mixed according to a mass ratio of phosphorene to iron powder is 1:0.57 to obtain a mixture” is replaced with “solid phosphorene purchased from Aladdin with article number B196539 and iron powder are mixed according to a mass ratio of phosphorene to iron powder is 1:1.02 to obtain a mixture”.

### Material Example 6

The present embodiment provides a composite and a film. Compared with the composite in Material Example 1, the composite in the present embodiment is different in that iron-doped phosphorene is replaced with manganese-doped phosphorene, and an atomic percentage of manganese in the manganese-doped phosphorene is 2.78%.

Compared with the film in Material Example 1, the film in the present embodiment has a difference that a material of the film includes the composite in the present embodiment. A method for preparing the film in the present embodiment is carried out with reference to Material Example 1.

A method for preparing manganese-doped phosphorene includes step S2.1 and step S2.2. In the step S2.1, solid phosphorene purchased from Aladdin with article number B196539 and manganese powder purchased from Aladdin with article number M118819 are mixed according to a mass ratio of phosphorene to manganese powder is 1:0.58 to obtain a mixture. In the step S2.2, the mixture is placed in a ball mill, a weight of ball milling media (agate balls) in the ball mill is 50 times of a weight of the mixture, and manganese-doped phosphorene is obtained after ball milling with a rotating speed of 400 r/min for 70 minutes. A band gap of manganese-doped phosphorene is 0.43 eV as calculated by the first principle thinking.

### Material Example 7

The present embodiment provides a composite and a film. Compared with the composite in Material Example 1, the composite in the present embodiment is different in that iron-doped phosphorene is replaced with cobalt-doped phosphorene, and an atomic percentage of cobalt in the cobalt-doped phosphorene is 2.78%.

Compared with the film in Material Example 1, the film in the present embodiment has a difference that a material of the film includes the composite in the present embodiment. A method for preparing the film in the present embodiment is carried out with reference to Material Example 1.

A method for preparing manganese-doped phosphorene includes step S3.1 and step S3.2. In the step S3.1, solid phosphorene purchased from Aladdin with article number B196539 and cobalt powder purchased from Aladdin with article number C104957 are mixed according to a mass ratio of phosphorene to cobalt powder is 1:0.54 to obtain a mixture. In the step S3.2, the mixture is placed in a ball mill, a weight of ball milling media (agate balls) in the ball mill is 50 times of a weight of the mixture, and cobalt-doped phosphorene is obtained after ball milling with a rotating speed of 400 r/min for 70 minutes. A band gap of manganese-doped phosphorene is 0.69 eV as calculated by the first principle thinking.

### Material Example 8

The present embodiment provides a composite and a film. Compared with the composite in Material Example 1, the composite in the present embodiment is different in that iron-doped phosphorene is replaced with phosphorene.

Compared with the film in Material Example 1, the film in the present embodiment has a difference that a material of the film includes the composite in the present embodiment. A method for preparing the film in the present embodiment is carried out with reference to Material Example 1.

### Material Example 9

The present embodiment provides a composite and a film. Compared with the composite in Material Example 1, the composite in the present embodiment is different in that TFB is replaced with polypyrrole.

Compared with the film in Material Example 1, the film in the present embodiment has a difference that a material of the film includes the composite in the present embodiment. A method for preparing the film in the present embodiment is carried out with reference to Material Example 1.

### Material Comparative Example 1

The present comparative embodiment provides a film. A material of the film is TFB, and an average thickness of the film is 30 nm.

A method for preparing the film includes a step that a TFB dispersion with a concentration of 10 mg/mL is spin-coated on a substrate under a nitrogen atmosphere at a normal temperature and a normal pressure, and then the film with an average thickness of 30 nm is obtained by heating at 170° C. under a nitrogen atmosphere for 15 minutes. A dispersion medium of the TFB dispersion is chlorobenzene.

### Material Comparative Example 2

The present comparative embodiment provides a film. A material of the film is phosphoene, and an average thickness of the film is 30 nm.

A method for preparing the film includes a step that a phosphoene dispersion purchased from Aladdin with article number B463005 is spin-coated on a substrate under a nitrogen atmosphere at a normal temperature and a normal pressure, and then the film with an average thickness of 30 nm is obtained by heating at 170° C. under a nitrogen atmosphere for 15 minutes.

### Material Comparative Example 3

The present comparative embodiment provides a composite and a film. The composite is formed of NiO nanoparticles with an average particle size of 5 nm and phosphorene. In the composite, a mass ratio of NiO nanoparticles to phosphorene is 50:1.

A material of the film includes the composite of the present comparative embodiment, and the film is made from the composite by a solution method. The solution method for preparing the film includes steps that a material dispersion with a concentration of 10 mg/mL is spin-coated on a substrate under a nitrogen atmosphere at a normal temperature and a normal pressure, and then the film with an average thickness of 30 nm is obtained by heating at 170° C. under a nitrogen atmosphere for 15 minutes. The material dispersion is prepared by steps that NiO nanoparticles, phosphorene, and chlorobenzene are mixed and ultrasonically dispersed at 60° C. for 3 hours.

### Device Example 1

This embodiment provides a photoelectric device and a preparation method thereof. The photoelectric device is a quantum dot light emitting diode with an upright structure. Referring to FIG. 1, the photoelectric device 10 includes an anode 101, a functional layer 103, and a cathode 102 disposed sequentially in stack. The functional layer 103 includes a hole functional layer 1032, a light-emitting layer 1031, and an electron functional layer 1033 disposed sequentially in stack, and the electron functional layer 1033 is closer to the cathode 102 than the hole functional layer 1032. The hole functional layer 1032 is formed of a hole injection layer 10321 and a hole transport layer 10322 disposed in stack, and the hole injection layer 10321 is closer to the anode 101 than the hole transport layer 10322. The electron functional layer 1033 has a single-layer structure, and the electron functional layer 1033 is an electron transport layer.

A material of the anode 101 is ITO, and an average thickness of the anode 101 is 50 nm. A material of the cathode 102 is silver, and an average thickness of the cathode 102 is 35 nm. A material of the light-emitting layer 1031 is a quantum dot with a core-shell structure, where a material of the core of the quantum dot is ZnCdS, a material of a shell of the quantum dot is ZnS, an emission wavelength of the quantum dot is 470 nm, and a thickness of the light-emitting layer 1031 is 40 nm. A material of the electron functional layer 1033 is Zn_{0.85}Mg_{0.15}O nanoparticles with an average particle size of 5 nm, and an average thickness of the electron functional layer 1033 is 40 nm. A material of the hole injection layer 10321 is PEDOT:PSS, and an average thickness of the hole injection layer 10321 is 100 nm. A material of the hole transport layer 10322 is the composite in Material Example 1, and an average thickness of the hole transport layer 10322 is 30 nm.

A method for preparing the photoelectric device includes steps S10.1˜S10.6.

In step S10.1, ITO is sputtered on one side of the substrate made of glass to obtain an ITO layer. A surface of the ITO layer is wiped with a cotton swab dipped in a small amount of soapy water to remove visible impurities on the surface. The substrate including the ITO layer is ultrasonically cleaned by deionized water for 15 minutes, acetone for 15 minutes, ethanol for 15 minutes and isopropyl alcohol for 15 minutes sequentially, and after drying, the substrate including the anode is obtained by an ultraviolet-ozone surface treatment for 15 minutes.

In step S10.2, a PEDOT: PSS aqueous solution is spin-coated on one side of the anode away from the substrate under an air atmosphere at a normal temperature and a normal pressure, and then the hole injection layer is formed by heating at 150° C. for 15 minutes.

In step S10.3, with reference to the method for preparing the film of Material Example 1, the hole transport layer is formed on one side of the hole injection layer away from the anode.

In step S10.4, a quantum dot solution with a concentration of 40 mg/mL is spin-coated on one side of the hole transport layer away from the hole injection layer under a nitrogen atmosphere at a normal temperature and a normal pressure, after a vacuum drying treatment for 15 minutes in a deposition chamber with a vacuum degree not higher than 3×10-4 Pa, the light-emitting layer is formed by heating at 100° C. under a nitrogen atmosphere for 10 minutes. A solvent of the quantum dot solution is n-octane.

In step S10.5, a Zn_{0.85}Mg_{0.15}O nanoparticles solution with a concentration of 30 mg/mL is spin-coated on one side of the light-emitting layer away from the hole transport layer under a nitrogen atmosphere at a normal temperature and a normal pressure, and then the electron functional layer is formed by heating at 100° C. under a nitrogen atmosphere for 15 minutes.

In step S10.6, a laminated structure obtained after the step S10.5 is placed in a vacuum coating machine with a vacuum degree not higher than 3×10⁻⁴ Pa, then the cathode is formed on one side of the electron functional layer away from the light-emitting layer by evaporating silver through a mask plate, and finally an epoxy resin adhesive is used for encapsulation to obtain the photoelectric device.

### Device Examples 2 to 9

A photoelectric device in Device Example n is basically the same as the photoelectric device in Device Example 1, except that in Device Example n, a material of the hole transport layer is the composite in Material Example n, correspondingly a method for preparing the hole transport layer in Device Example n is performed with reference to the method for preparing the film in Material Example n, and n is a positive integer of 2 to 9.

For example, in Device Example 2, the material of the hole transport layer is the composite in Material Example 2, and a method for preparing the hole transport layer in Device Example 2 is performed with reference to the method for preparing the film of Material Example 2. In Device Example 3, the material of the hole transport layer is the composite in Material Example 3, and a method for preparing the hole transport layer in Device Example 3 is performed with reference to the method for preparing the film of Material Example 3, and the like.

### Device Example 10

The present embodiment provides a photoelectric device and a preparation method thereof. Compared with the photoelectric device in Device Example 1, the photoelectric device in the present embodiment is different in that the material of the hole transport layer is iron-doped phosphorene, and an atomic percentage of iron in the iron-doped phosphorene is 2.78%.

Compared with the method for preparing the photoelectric device in Device Example 1, a method for preparing the photoelectric device in the present embodiment is different in that the step S10.3 is replaced with “an iron-doped phosphorene dispersion with a concentration of 10 mg/mL is spin-coated on one side of the hole injection layer away from the anode under a nitrogen atmosphere at a normal temperature and a normal pressure, and then the hole transport layer is obtained by heating at 170° C. under a nitrogen atmosphere for 15 minutes”. A dispersion medium of the iron-doped phosphorene dispersion is chlorobenzene.

### Device Example 11

The present embodiment provides a photoelectric device and a preparation method thereof. Compared with the photoelectric device in Device Example 1, the photoelectric device in the present embodiment is different in that an average thickness of the hole transport layer is 10 nm, and an average thickness of the light-emitting layer is 60 nm.

A method for preparing the photoelectric device in the present embodiment is performed with reference to Device Example 1.

### Device Comparative Example 1

The present comparative embodiment provides a photoelectric device and a preparation method thereof. Compared with the photoelectric device in Device Example 1, the photoelectric device in the present embodiment is different in that the material of the hole transport layer is replaced with TFB.

Compared with the method for preparing the photoelectric device in Device Example 1, a method for preparing the photoelectric device in the present comparative embodiment is different in that the step S10.3 is replaced with “a TFB dispersion with a concentration of 10 mg/mL is spin-coated on one side of the hole injection layer away from the anode, and then the hole transport layer is obtained by heating at 170° C. under a nitrogen atmosphere for 15 minutes”. A dispersion medium of the TFB solution is chlorobenzene.

### Device Comparative Example 2

The present comparative embodiment provides a photoelectric device and a preparation method thereof. Compared with the photoelectric device in Device Example 1, the photoelectric device in the present embodiment is different in that the material of the hole transport layer is replaced with phosphorene.

Compared with the method for preparing the photoelectric device in Device Example 1, a method for preparing the photoelectric device in the present comparative embodiment is different in that the step S10.3 is replaced with “a phosphorene dispersion with a concentration of 10 mg/mL is spin-coated on one side of the hole injection layer away from the anode, and then the hole transport layer is obtained by heating at 170° C. under a nitrogen atmosphere for 15 minutes”. A dispersion medium of the phosphorene solution is chlorobenzene.

### Device Comparative Example 3

The present comparative embodiment provides a photoelectric device and a preparation method thereof. Compared with the photoelectric device in Device Example 1, the photoelectric device in the present embodiment is different in that the material of the hole transport layer is replaced with the composite in Material Comparative Example 3.

Compared with the method for preparing the photoelectric device in Device Example 1, a method for preparing the photoelectric device in the present comparative embodiment is different in that the step S10.3 is replaced with “with reference to the method for preparing the film in Material Comparative Example 3, the hole transport layer is formed on one side of the hole injection layer away from the anode”.

### Device Comparative Example 4

The present comparative embodiment provides a photoelectric device and a preparation method thereof. Compared with the photoelectric device in Device Example 1, the photoelectric device in the present embodiment is different in that the material of the hole transport layer is replaced with polypyrrole.

Compared with the method for preparing the photoelectric device in Device Example 1, a method for preparing the photoelectric device in the present comparative embodiment is different in that the step S10.3 is replaced with “a polypyrrole dispersion with a concentration of 10 mg/mL is spin-coated on one side of the hole injection layer away from the anode, and then the hole transport layer is obtained by heating at 170° C. under a nitrogen atmosphere for 15 minutes”. A dispersion medium of the phosphorene solution is chlorobenzene.

### Test Example

Performances of photoelectric devices after one hour of the encapsulation in Device Examples 1 to 11 and Device Comparative Examples 1 to 4 are tested. The performance test is performed at a temperature of 25° C. and a relative humidity of 50%.

A turn-on voltage, currents, brightness, a luminescence spectrum and other parameters of each photoelectric device are obtained by a Fostar FPD optical characteristic measuring equipment, and then some key parameters such as an external quantum efficiency and a power efficiency are calculated.

Brightness values of the photoelectric device are intermittently collected at a driving voltage in a range of 0 V to 8 V, where an area of a light-emitting region collected is 0.04 cm², a voltage value of initially collected brightness is 3 V, and a brightness value is collected every 0.2 V. A brightness value collected every time is divided by a corresponding current density to obtain a current efficiency of the photoelectric device under a collection condition, thus the maximum current efficiency (C.Emax, cd/A) is obtained, and a current density of the photoelectric device at 1000 nit (J@1000 nit, A/m²) is obtained.

Driven by a constant current (2 mA), an electroluminescence lifetime of each photoelectric device is analyzed by a 128-channel QLED lifetime test system. A time required for each photoelectric device to decay from the maximum brightness to 95% thereof is recorded. A time required for each photoelectric device to decay from 100% to 95% at 1000 nit brightness is calculated by attenuation fitting formula, and the time is defined as T95@1000 nit. A specific calculation formula is as follows:

$$T {95}_{L} = T {95}_{H} * {( \frac{{L}_{H}}{{L}_{L}} )}^{A} ;$$

In the formula, T95_{L} is a lifetime at low brightness, T95_{H} is a measured lifetime at high brightness, LH is the highest brightness of the device, LL is 1000 nit, and A is an acceleration factor which is 1.7.

Test results of photoelectric devices are shown in Table 1 below:

TABLE 1

| | U_{T} | C.Eₘₐₓ | T95@1000 nit | J@1000 nit |
|---|---|---|---|---|
| items | (V) | (cd/A) | (h) | (A/m²) |
| Device | 3.5 | 22.80 | 196.95 | 8.1 |
| Example 1 | | | | |
| Device | 3.7 | 20.14 | 150.63 | 8.3 |
| Example 2 | | | | |
| Device | 3.4 | 23.70 | 199.34 | 7.9 |
| Example 3 | | | | |
| Device | 3.9 | 18.75 | 163.48 | 13.5 |
| Example 4 | | | | |
| Device | 3.2 | 23.84 | 202.31 | 7.8 |
| Example 5 | | | | |
| Device | 3.8 | 19.66 | 169.29 | 10.2 |
| Example 6 | | | | |
| Device | 3.9 | 18.34 | 143.82 | 11.7 |
| Example 7 | | | | |
| Device | 4.5 | 20.67 | 156.34 | 10.9 |
| Example 8 | | | | |
| Device | 4.4 | 18.41 | 107.9 | 13.0 |
| Example 9 | | | | |
| Device | 4.2 | 10.64 | 13.62 | 20.1 |
| Example 10 | | | | |
| Device | 5.4 | 16.48 | 123.88 | 12.2 |
| Example 11 | | | | |
| Device | 4.6 | 17.35 | 102.62 | 12.6 |
| Comparative | | | | |
| Example 1 | | | | |
| Device | 4.3 | 6.16 | 12.37 | 19.4 |
| Comparative | | | | |
| Example 2 | | | | |
| Device | 4.1 | 17.28 | 110.3 | 12.4 |
| Comparative | | | | |
| Example 3 | | | | |
| Device | 4.7 | 15.31 | 100.26 | 11.2 |
| Comparative | | | | |
| Example 4 | | | | |

As can be seen from Table 1, compared with photoelectric devices in Device Comparative Examples 1 to 4, performances of photoelectric devices in Device Examples 1 to 9 and 11 are better. Compared with the photoelectric device in Device Comparative Example 2, performance of the photoelectric device in Device Example 10 is better.

Taking the photoelectric device in Device Example 1 and Device Comparative Example 1 as examples, the UT of the photoelectric device in Device Example 1 is 1.1 V lower than that of the photoelectric device in Device Comparative Example 1, the C.Emax of the photoelectric device in Device Example 1 is 1.3 times of that of the photoelectric device in Device Comparative Example 1, and the T95@1000 nit of the photoelectric device in Device Example 1 is 1.9 times of that of the photoelectric device in Device Comparative Example 1, and the J@1000 nit of the photoelectric device in Device Example 1 is 64.3% of that of the photoelectric device in Device Comparative Example 1. The J@1000 nit of the photoelectric device in Device Example 1 is lower than that of the photoelectric device in Device Comparative Example 1, indicating that the device efficiency of the photoelectric device in Device Example 1 is higher, because only a smaller current density is required to achieve the brightness of 1000 nit. It is demonstrated that a resistance of the photoelectric device in Device Example 1 is smaller and an electron-hole recombination efficiency is higher. It is further demonstrated that a hole transport material of the photoelectric device in Device Example 1 has higher conductivity.

Therefore, the composite configured as the material of the hole transport layer in the photoelectric device may improve the device efficiency and the device lifetime of the photoelectric device. The material of the hole transport layer in the Device Comparative Example 1 is TFB and the material of the hole transport layer in the Device Comparative Example 4 is polypyrrole. Both TFB and polypyrrole belong to the organic hole transport material, and the organic hole transport material has an advantage of high film-forming quality, but the organic hole-functional material has poor conductivity, and there is a large band gap difference between the organic hole transport material and the quantum dot, resulting in low hole transport efficiency, and thus a comprehensive performance of each of photoelectric devices in Device Comparative Example 1 and 4 is poor.

A hole transport material of the photoelectric device in Device Comparative Example 2 is phosphorene. As phosphorene may lead to a problem of “darkening” of the photoelectric device, the device efficiency and the device lifetime may decrease. The hole transport material of the photoelectric device in Device Comparative Example 3 is NiO nanoparticles and phosphorene, resulting in poor film-forming quality of the hole transport layer, and thus the comprehensive performance of the photoelectric device is inferior to that of photoelectric devices in Device Examples 1 to 8 and 10.

The composite, the film, and the photoelectric device by embodiments of the present disclosure are described in detail above, and specific examples have been applied herein to illustrate principles and implement measures. The foregoing description of embodiments is provided merely to help understand a method and a core idea of the present disclosure. Those skilled in the art may change specific embodiments and scope of the present disclosure according to ideas of the present disclosure. In summary, contents of the specification should not be construed as limiting the present disclosure.

What is claimed is:

1. A composite comprising a first material and a second material, wherein the first material is an organic P-type semiconductor material, and the second material is selected from one or more of phosphorene and a first metal element doped phosphorene.

2. The composite according to claim 1, wherein a mass ratio of the second material to the first material is 1: (30˜70).

3. The composite according to claim 1, wherein in the first metal element doped phosphorene, an atomic percentage of the first metal element ranges from 1% to 5%; and
the first metal element doped phosphorene has a layered structure, and a number of layers of the layered structure ranges from one layer to ten layers; an average sheet diameter of the first metal element doped phosphorene ranges from 100 nm to 200 nm.

4. The composite according to claim 1, wherein the first metal element is selected from one or more of Cr, Mg, Fe, Co, and Ni.

5. The composite according to claim 1, wherein a band gap of the first metal element doped phosphorene ranges from 0.2 eV to 0.4 eV.

6. The composite according to claim 1, wherein the organic P-type semiconductor material is selected from one or more of an organic hole transport material and an organic hole injection material; the organic hole injection material is selected from one or more of poly(3,4-ethylenedioxythiophene)-poly(styrenesulfonate), copper(II) phthalocyanine, titanyl phthalocyanine, 2,3,5,6-tetrafluoro-7,7,8,8-tetracyanoquinodimethane, and hexaazatriphenylenehexacabonitrile; and
the organic hole transport material is selected from one or more of polyaniline, polypyrrole, poly(3-hexylthiophene-2,5-diyl), poly(n-vinylcarbazole), 4,4′-Bis(N-carbazolyl)-1,1′-biphenyl, poly[N,N′-bis(4-butylphenyl)-N,N′-bis(phenyl)-benzi, 4,4′-cyclohexylidenebis[N,N-bis(4-methylphenyl)aniline], poly(9,9-dioctylfluorene-co-N-(4-butylphenyl)diphenylamine), poly[(9,9-dioctylfluorenyl-2,7-diyl)-alt-(4,4′-(N-(4-butylphenyl), 4,4′,4″-tris(N-3-methylphenyl-N-phenylamino)triphenylamine, 4,4′,4″-tris(carbazol-9-yl)-triphenylamine, 4,4′,4″-tris[2-naphthyl(phenyl)amino]triphenylamine, N,N′-bis-(1-naphthalenyl)-N,N′-bis-phenyl-(1,1′-biphenyl)-4,4′-diamine, N,N′-bis(3-methylphenyl)-N,N′-diphenyl-benzidine, N,N′-bis[4-(diphenylamino)phenyl]-N,N′-diphenylbenzidine, N,N′-Bis(3-methylphenyl)-N,N′-diphenyl-9,9-spirobifluorene-2,7-diamine, N2,N7-di-1-naphthalenyl-N2,N7-diphenyl-9,9′-spirobi[9h-fluorene]-2,7-diamine, poly[bis(4-phenyl)(2,4,6-trimethylphenyl)amine], and 2,2′,7,7′-Tetrakis[N,N-di(4-methoxyphenyl)amino]-9,9′-spirobifluorene.

7. The composite according to claim 1, wherein the first material is selected from one or more of poly(9,9-dioctylfluorene-co-N-(4-butylphenyl)diphenylamine), polyaniline, and polypyrrole, and the second material is iron-doped phosphorene.

8. A film comprising a composite, wherein the composite comprising a first material and a second material; the first material is an organic P-type semiconductor material, and the second material is selected from one or more of phosphorene and a first metal element doped phosphorene.

9. The film according to claim 8, wherein a mass ratio of the second material to the first material is 1: (30˜70).

10. The film according to claim 8, wherein in the first metal element doped phosphorene, an atomic percentage of the first metal element ranges from 1% to 5%; and
the first metal element doped phosphorene has a layered structure, and a number of layers of the layered structure ranges from one layer to ten layers; and
an average sheet diameter of the first metal element doped phosphorene ranges from 100 nm to 200 nm.

11. The film according to claim 8, wherein the first metal element is selected from one or more of Cr, Mg, Fe, Co, and Ni, and a band gap of the first metal element doped phosphorene ranges from 0.2 eV to 0.4 eV.

12. The film according to claim 8, the organic P-type semiconductor material is selected from one or more of an organic hole transport material and an organic hole injection material; the organic hole injection material is selected from one or more of poly(3,4-ethylenedioxythiophene)-poly(styrenesulfonate), copper(II) phthalocyanine, titanyl phthalocyanine, 2,3,5,6-tetrafluoro-7,7,8,8-tetracyanoquinodimethane, and hexaazatriphenylenehexacabonitrile; and
the organic hole transport material is selected from one or more of polyaniline, polypyrrole, poly(3-hexylthiophene-2,5-diyl), poly(n-vinylcarbazole), 4,4′-Bis(N-carbazolyl)-1,1′-biphenyl, poly[N,N′-bis(4-butylphenyl)-N,N′-bis(phenyl)-benzi, 4,4′-cyclohexylidenebis[N,N-bis(4-methylphenyl)aniline], poly(9,9-dioctylfluorene-co-N-(4-butylphenyl)diphenylamine), poly[(9,9-dioctylfluorenyl-2,7-diyl)-alt-(4,4′-(N-(4-butylphenyl), 4,4′,4″-tris(N-3-methylphenyl-N-phenylamino)triphenylamine, 4,4′,4″-tris(carbazol-9-yl)-triphenylamine, 4,4′,4″-tris[2-naphthyl(phenyl)amino]triphenylamine, N,N′-bis-(1-naphthalenyl)-N,N′-bis-phenyl-(1,1′-biphenyl)-4,4′-diamine, N,N′-bis(3-methylphenyl)-N,N′-diphenyl-benzidine, N,N′-bis[4-(diphenylamino)phenyl]-N,N′-diphenylbenzidine, N,N′-Bis(3-methylphenyl)-N,N′-diphenyl-9,9-spirobifluorene-2,7-diamine, N2,N7-di-1-naphthalenyl-N2,N7-diphenyl-9,9′-spirobi[9h-fluorene]-2,7-diamine, poly[bis(4-phenyl)(2,4,6-trimethylphenyl)amine], and 2,2′,7,7′-Tetrakis[N,N-di(4-methoxyphenyl)amino]-9,9′-spirobifluorene.

13. A photoelectric device comprising:
an anode;
a cathode; and
a functional layer disposed between the anode and the cathode, wherein the functional layer comprises multiple functional sublayers disposed in stack, and a material of at least one of the multiple functional sublayers comprises a second material selected from one or more of phosphorene and a first metal element doped phosphorene.

14. The photoelectric device according to claim 13, in the first metal element doped phosphorene, an atomic percentage of the first metal element ranges from 1% to 5%; and
the first metal element doped phosphorene has a layered structure, and a number of layers of the layered structure ranges from one layer to ten layers; and
an average sheet diameter of the first metal element doped phosphorene ranges from 100 nm to 200 nm; the first metal element is selected from one or more of Cr, Mg, Fe, Co, and Ni, and a band gap of the first metal element doped phosphorene ranges from 0.2 eV to 0.4 eV.

15. The photoelectric device according to claim 14, the material of at least one of the multiple functional sublayers further comprises a first material, and the first material is an organic P-type semiconductor material.

16. The photoelectric device according to claim 15, a mass ratio of the second material to the first material is 1: (30˜70); and
the organic P-type semiconductor material is selected from one or more of an organic hole transport material and an organic hole injection material; the organic hole injection material is selected from one or more of poly(3,4-ethylenedioxythiophene)-poly(styrenesulfonate), copper(II) phthalocyanine, titanyl phthalocyanine, 2,3,5,6-tetrafluoro-7,7,8,8-tetracyanoquinodimethane, and hexaazatriphenylenehexacabonitrile; and
the organic hole transport material is selected from one or more of polyaniline, polypyrrole, poly(3-hexylthiophene-2,5-diyl), poly(n-vinylcarbazole), 4,4′-Bis(N-carbazolyl)-1,1′-biphenyl, poly[N,N′-bis(4-butylphenyl)-N,N′-bis(phenyl)-benzi, 4,4′-cyclohexylidenebis[N,N-bis(4-methylphenyl)aniline], poly(9,9-dioctylfluorene-co-N-(4-butylphenyl)diphenylamine), poly[(9,9-dioctylfluorenyl-2,7-diyl)-alt-(4,4′-(N-(4-butylphenyl), 4,4′,4″-tris(N-3-methylphenyl-N-phenylamino)triphenylamine, 4,4′,4″-tris(carbazol-9-yl)-triphenylamine, 4,4′,4″-tris[2-naphthyl(phenyl)amino]triphenylamine, N,N′-bis-(1-naphthalenyl)-N,N′-bis-phenyl-(1,1′-biphenyl)-4,4′-diamine, N,N′-bis(3-methylphenyl)-N,N′-diphenyl-benzidine, N,N′-bis[4-(diphenylamino)phenyl]-N,N′-diphenylbenzidine, N,N′-Bis(3-methylphenyl)-N,N′-diphenyl-9,9-spirobifluorene-2,7-diamine, N2,N7-di-1-naphthalenyl-N2,N7-diphenyl-9,9′-spirobi[9h-fluorene]-2,7-diamine, poly[bis(4-phenyl)(2,4,6-trimethylphenyl)amine], and 2,2′,7,7′-Tetrakis[N,N-di(4-methoxyphenyl)amino]-9,9′-spirobifluorene.

17. The photoelectric device according to claim 15, the multiple functional sublayers comprise a hole functional layer comprising one or more of a hole injection layer and a hole transport layer, and when the hole functional layer comprises the hole injection layer and the hole transport layer, the hole injection layer is closer to the anode than the hole transport layer; and
a material of the hole injection layer comprises the second material, or the material of the hole injection layer is formed of the first material and the second material; the first material is the organic hole injection material; and
a material of the hole transport layer comprises the second material, or the material of the hole transport layer is formed of the first material and the second material; the first material is the organic hole transport material.

18. The photoelectric device according to claim 17, the multiple functional sublayers further comprise a light-emitting layer disposed between the hole functional layer and the cathode, and a material of the light-emitting layer comprises one or more of an organic light-emitting material and a quantum dot; and
the multiple functional sublayers further comprise an electron functional layer disposed between the hole functional layer and the cathode, the electron functional layer comprises one or more of an electron injection layer and an electron transport layer, and when the electron functional layer comprises the electron injection layer and the electron transport layer, the electron injection layer is closer to the cathode than the electron transport layer.

19. The photoelectric device according to claim 18, the quantum dot is selected from one or more of a quantum dot with a single component, a quantum dot with a core-shell structure, an inorganic perovskite quantum dot, an organic perovskite quantum dot, and an organic-inorganic hybrid perovskite quantum dot; the quantum dot with a core-shell structure comprises one or more shell layers;
a material of the quantum dot with a single component, a material of the core of the quantum dot with a core-shell structure, and a material of a shell layer of the quantum dot with a core-shell structure are each independently selected from one or more of a group II-VI compound, a group IV-VI compound, a group III-V compound, a group III-VI compound, and a group I-III-VI compound;
the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the group III-VI compound is selected from one or more of In₂S₃, In₂Se₃, InGaS₃, and InGaSe₃; the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the group I-III-VI compound is selected from one or more of AgInS, AgInS₂, CuInS, CuInS₂, AgGaS₂, CuGaS₂, CuGaO₂, AgGaO₂, AgAlO₂, AgInGaS₂, and CuInGaS₂;
the inorganic perovskite quantum dot has a general structural formula of AMX₃, wherein A is Cs⁺, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion selected from one or more of Cl⁻, Br⁻, and I⁻;
the organic perovskite quantum dot has a general structural formula of CMX₃, where C is a formamidyl, M is a divalent metal cation selected from Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion selected from Cl⁻, Br⁻, or I⁻;
the organic-inorganic hybrid perovskite quantum dot has a general structural formula of BMX₃, where B is an organic amine cation, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion selected from one or more of Cl⁻, Br⁻, or I⁻; and
a material of the electron functional layer comprises one or more of a second metal oxide material, a third metal oxide material, and a group IIB-VIA semiconductor material; the second metal oxide material comprises one or more of ZnO, TiO₂, and SnO₂; the group IIB-VIA semiconductor material comprises one or more of ZnS, ZnSe, and CdS; the third metal oxide material comprises one or more of a doped-type metal oxide, a host compound is selected from one or more of ZnO, TiO₂, and SnO₂, and a doping element of the doped-type metal oxide is selected from one or more of Mg, Ca, Zr, W, Ga, Li, Al, Ti, Y, In, and Sn.

20. The photoelectric device according to claim 18, wherein the multiple functional sublayers are formed of the hole injection layer, the hole transport layer, the light-emitting layer, and the electron functional layer; the material of the hole injection layer is the organic hole injection material, and the material of the hole transport layer is selected from one or more of the first metal element doped phosphorene and a composite comprising the first material and the second material.
